(19) United States
(12) Patent Application Publication
(10) Pub. No.: US 2020/0089118 A1
(43) Pub. Date: Mar. 19, 2020

(54) FOIL TRANSFER DEVICE

(71) Applicant: DGSHAPE Corporation, Hamamatsu-shi (JP)

(72) Inventor: Tsutomu KUNO, Hamamatsu-shi (JP)

(21) Appl. No.: 16/550,572

(22) Filed: Aug. 26, 2019

(30) Foreign Application Priority Data
Sep. 14, 2018 (JP) 2018-172349

(51) Int. Cl. G03F 7/20

(52) U.S. Cl. CPC G03F 7/2008

(57) ABSTRACT

A foil transfer device includes a holding table to hold a work, a light irradiation device spaced away from the holding table to irradiate the work held by the holding table with light, and a presser between the holding table and the light irradiation device. The work includes a transfer target, a heat transfer foil and a heat generator stacked on each other. The light irradiation device includes a light source, and an irradiation position moving mechanism to move a position irradiated with light from the light source. The presser includes a light-transmissive portion to press the work toward the holding table to put the transfer target, the heat transfer foil and the heat generator into close contact with each other, and to transmit the light from the light irradiation device to allow the light to reach the work.

### CROSS REFERENCE TO RELATED APPLICATION

This application claims the benefit of priority to Japanese Patent Application No. 2018-172349 filed on Sep. 14, 2018. The entire contents of this application are hereby incorporated herein by reference.

### BACKGROUND OF THE INVENTION

### 1. Field of the Invention

The present invention relates to a foil transfer device.

### 2. Description of the Related Art

Conventionally, a foil transfer device using a heat transfer foil is known. Foil transfer is performed as follows by a foil transfer device. A heat transfer foil is stacked on a transfer target, and is heated while being pressed from above by a foil transfer tool. As a result, an image is transferred onto a surface of the transfer target. For example, Japanese Laid-Open Patent Publication No. 2016-215599 discloses a foil transfer device including an optical pen that directs laser light as the foil transfer tool.

In a conventional foil transfer device, a foil transfer tool presses a heat transfer foil and a transfer target during foil transfer. Therefore, the foil transfer tool is moved while pressing the heat transfer foil and the transfer target during the foil transfer. Due to a load of pressing a work (including the heat transfer foil and the transfer target), it is difficult to move the foil transfer tool on the work at a high speed. For this reason, a transfer position on the transfer target, namely, the position onto which the foil transfer is performed, cannot be moved at a high speed, which does not provide a high productivity.

### SUMMARY OF THE INVENTION

Preferred embodiments of the present invention provide foil transfer devices each capable of moving a transfer position quickly and thus improving the productivity.

A foil transfer device disclosed herein includes a holding table to hold a work; a light irradiation device spaced away from the holding table to irradiate the work held by the holding table with light; and a presser between the holding table and the light irradiation device. The work includes a transfer target, a heat transfer foil and a heat generator that are stacked on each other, the heat generator generating heat upon receiving the light from the light irradiation device. The holding table holds the work such that the transfer target, the heat transfer foil and the heat generator face the presser. The light irradiation device includes a light source, and an irradiation position moving mechanism to move a position irradiated with light from the light source. The presser includes a light-transmissive portion to press the work toward the holding table to put the transfer target, the heat transfer foil and the heat generator into contact with each other, and to transmit the light from the light irradiation device to allow the light to reach the work.

Another foil transfer device disclosed herein includes a holding table to hold a work; a light irradiation device spaced away from the holding table to irradiate the work held by the holding table with light; a moving device to move the light irradiation device with respect to the holding table; and a presser between the holding table and the light irradiation device. The work includes a transfer target, a heat transfer foil and a heat generator stacked on each other, the heat generator generating heat upon receiving the light from the light irradiation device. The holding table holds the work such that the transfer target, the heat transfer foil and the heat generator face the presser. The moving device includes a first moving device and a second moving device. The first moving device moves the light irradiation device in a first direction with respect to the holding table, the first direction being non-parallel to a direction in which the transfer target, the heat transfer foil and the heat generator are stacked on each other. The second moving device moves the light irradiation device in a second direction with respect to the holding table, the second direction being non-parallel to the direction in which the transfer target, the heat transfer foil and the heat generator are stacked on each other and also non-parallel to the first direction. The presser includes a light-transmissive portion to press the work toward the holding table to put the transfer target, the heat transfer foil and the heat generator into contact with each other, and to transmit the light from the light irradiation device to allow the light to reach the work.

In such a foil transfer device, the presser puts the transfer target, the heat transfer foil and the heat generator into contact with each other, and the light irradiation device is spaced away from the work. Light for foil transfer transmits the light-transmissive portion to reach the work. The position irradiated with the light is moved by the irradiation position moving mechanism of the light irradiation device or by the moving device. With such a structure, the light irradiation device or the moving device moves the transfer position with no influence of the operation of pressing the work. Therefore, the transfer position is moved quickly, and thus the productivity is improved.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a perspective view showing a foil transfer device according to preferred embodiment 1 of the present invention.

FIG. 2 is a side view schematically showing a portion of the foil transfer device.

FIG. 3 is a plan view schematically showing a holding table and a pressing mechanism in a state where a presser is at a first position.

FIG. 4 is a plan view schematically showing the holding table and the pressing mechanism in a state where the presser is at a second position.

FIG. 5 schematically shows a structure of a light irradiation device.

FIG. 6 is a perspective view schematically showing a work during foil transfer.

FIG. 7 is a perspective view of a foil transfer device according to preferred embodiment 2 of the present invention.

FIG. 8 is a side view schematically showing a structure of a light irradiation device according to preferred embodiment 2.

FIG. 9 is a partially-cut perspective view of a foil transfer device according to preferred embodiment 3 of the present invention.

### DETAILED DESCRIPTION OF THE PREFERRED EMBODIMENTS

Hereinafter, foil transfer devices according to preferred embodiments of the present invention will be described with reference to the drawings. The preferred embodiments described herein are not intended to specifically limit the present invention. Elements and portions that have the same functions will bear the same reference signs, and overlapping descriptions will be omitted or simplified.

### Preferred Embodiment 1

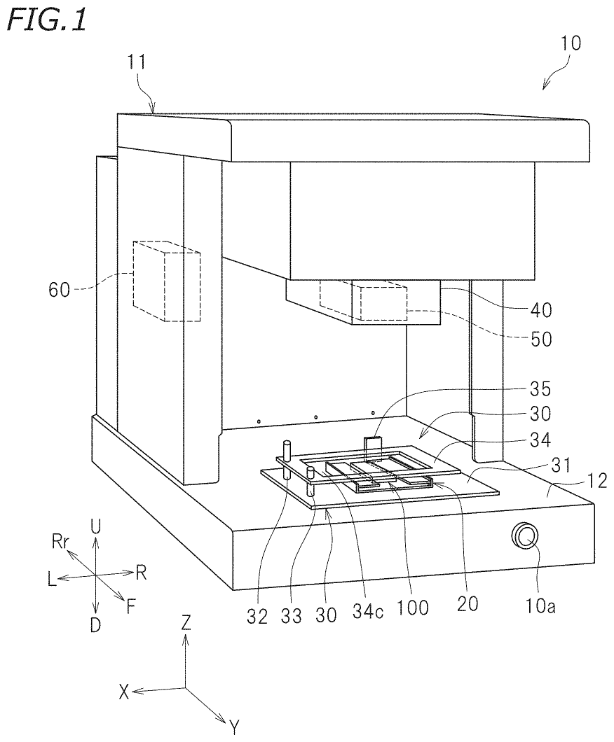

FIG. 1 is a perspective view of a foil transfer device 10. In the following description, the terms “left”, “right”, “up” and “down” respectively refer to left, right, up and down as seen from a user looking at a power switch 10a on a front surface of the foil transfer device 10. A direction in which the user approaches the foil transfer device 10 is referred to as “rearward”, and a direction in which the user is distanced away from the foil transfer device 10 is referred to as “forward”. In the drawings, letters F, Rr, L, R, U and D respectively represent front, rear, left, right, up and down. Where an X axis, a Y axis and a Z axis cross each other perpendicularly, the foil transfer device 10 in this preferred embodiment is placed on a plane defined by the X axis and the Y axis. In this preferred embodiment, the X axis extends in a left-right direction. The Y axis extends in a front-rear direction. The Z axis extends in an up-down direction. The above-described directions are merely defined for the sake of convenience, and do not limit the manner of installation of the foil transfer device 10 in any way.

As shown in FIG. 1, the foil transfer device 10 has a box shape. The foil transfer device 10 includes a housing 11 having a front opening. The housing 11 accommodates a holding table 20 to hold a work 100, a pressing mechanism 30 to press the work 100, a head 40 having a light irradiation device 50 mounted thereon, and a controller 60. The housing 11 is formed of, for example, a steel plate.

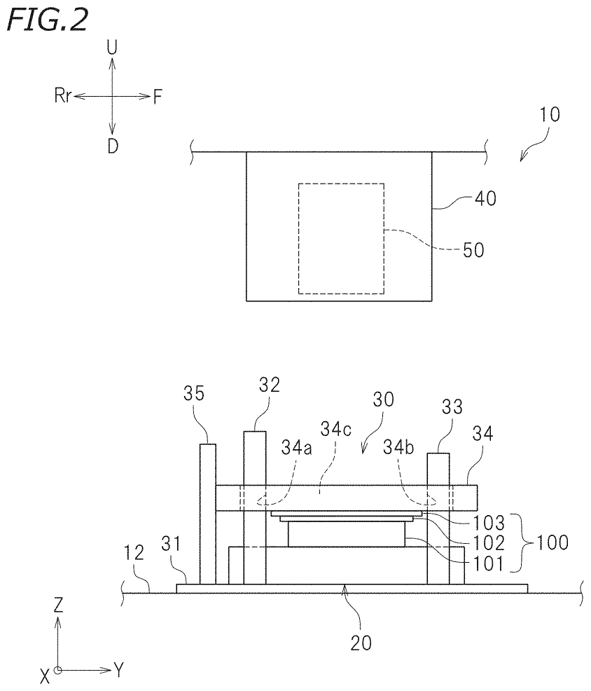

FIG. 2 is a side view schematically showing a portion of the foil transfer device 10. As shown in FIG. 2, the work 100 includes a transfer target 101, a heat transfer foil 102 and a light absorbing film 103. The light absorbing film 103 is a heat generator that generates heat upon receiving light. The work 100 may include any element other than the above-described elements; for example, a decoration film having convex and concave portions at a surface thereof. The decoration film is a film to transfer the convex and concave portions at the surface thereof onto the transfer target 101 to provide a visual effect. The transfer target 101, the heat transfer foil 102 and the light absorbing film 103 are stacked in this order, with the transfer target 101 being the lowest layer. The transfer target 101, the heat transfer foil 102 and the light absorbing film 103 will be described below in detail.

As shown in FIG. 1, the holding table 20 is provided on a bottom portion 12 of the housing 11. In more detail, the holding table 20 is placed on a base 31 of the pressing mechanism 30 provided on the bottom portion 12. The holding table 20 is attachable to, and detachable from, the base 31. Alternatively, the holding table 20 may be undetachably secured to the base 31. The holding table 20 holds the work 100. The holding table 20 is, for example, a vise. The holding table 20 is configured to grasp the transfer target 101.

There is no specific limitation on the material or the shape of the transfer target 101. The transfer target 101 may be formed of, for example, a resin such as an acrylic resin, polyvinylchloride (PVC), polyethyleneterephthalate (PET), polycarbonate (PC) or the like; paper such as plain paper, drawing paper, Japanese “washi” paper or the like; rubber; or the like.

The heat transfer foil 102 is stacked on the transfer target 101. The heat transfer foil 102 is a foil that is heated in close contact with the transfer target 101 so as to have an image transferred onto a surface of the transfer target 101. In this preferred embodiment, heat transfer is performed by optical energy of light directed from the light irradiation device 50 toward the heat transfer foil 102. The heat transfer foil 102 may be any common transfer foil commercially available for heat transfer with no specific limitation. The heat transfer foil 102 generally includes a substrate, a decoration layer, and an adhesive layer stacked in this order. The decoration layer of the heat transfer foil 102 may be, for example, a metallic foil such as a gold foil, a silver foil or the like, a half metallic foil, a pigment foil, a multi-color printed foil, a hologram foil, an electrostatic discharge-preventive foil or the like.

The light absorbing film 103 is stacked on the heat transfer foil 102. The light absorbing film 103 is an example of heat generator that generates heat upon receiving light directed from the light irradiation device 50. The light absorbing film 103 efficiently absorbs light having a wavelength in a predetermined wavelength range (laser light) directed from the light irradiation device 50, and converts the optical energy into thermal energy. The light absorbing film 103 is formed of a resin such as, for example, polyimide. The light absorbing film 103 has a resistance against heat of, for example, about 100° C. to about 200° C.

In this preferred embodiment, the light absorbing film 103 and the heat transfer foil 102 are separately formed from each other. Alternatively, the light absorbing film 103 and the heat transfer foil 102 may be formed as one sheet. For example, a light absorber having an equivalent function to that of the light absorbing film 103 may be formed on the heat transfer foil 102. There is no specific limitation on whether a heat generator and a heat transfer foil are to be integrally formed with each other or separately formed from each other.

As shown in FIG. 1 and FIG. 2, the holding table 20 holds the work 100 such that the transfer target 101, the heat transfer foil 102 and the light absorbing film 103 face the pressing mechanism 30. In this preferred embodiment, the holding table 20 holds the work 100 such that the transfer target 101, the heat transfer foil 102 and the light absorbing film 103 are stacked on each other in the up-down direction. The pressing mechanism 30 is located above the work 100. The work 100 expands in a horizontal direction (X-Y plane) while being held by the holding table 20.

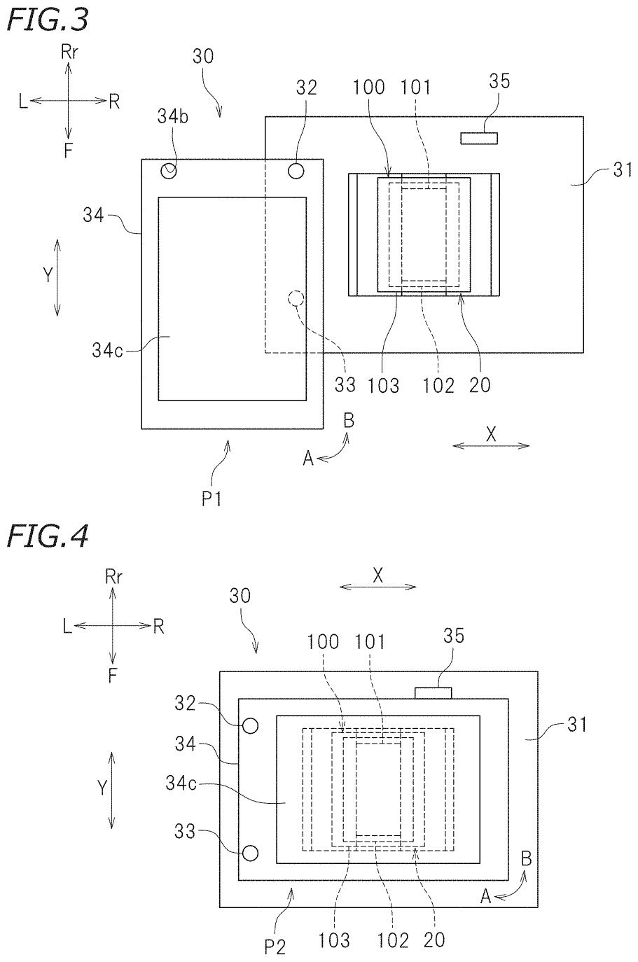

The pressing mechanism 30 puts the heat transfer foil 102 and the light absorbing film 103 into close contact with the transfer target 101. The pressing mechanism 30 is provided on the bottom portion 12 of the housing 11. FIG. 3 and FIG. 4 are each a plan view schematically showing the holding table 20 and the pressing mechanism 30. As shown in FIG. 3 and FIG. 4, the pressing mechanism 30 includes a base 31, a first slide bar 32, a second slide bar 33, a presser 34, and a stopper 35. As described below in detail, the presser 34 is rotatable along the horizontal plane. FIG. 3 shows a state where the presser 34 is at a first position P1, which is one of rotation positions thereof. FIG. 4 shows a state where the presser 34 is at a second position P2, which is another one of the rotation positions thereof.

As shown in FIG. 2, the base 31 is provided on the bottom portion 12. The base 31 is a flat plate. The first slide bar 32 and the second slide bar 33 extend upward from the base 31. The first slide bar 32 and the second slide bar 33 extend upward from a left end of the base 31. The first slide bar 32 is located to the rear of the second slide bar 33. The first slide bar 32 and the second slide bar 33 are parallel or substantially parallel to each other. The first slide bar 32 is longer than the second slide bar 33 in the up-down direction.

As shown in FIG. 2, the presser 34 is movable in the up-down direction along the first slide bar 32 and the second slide bar 33. The presser 34 is located above the base 31. As shown in FIG. 3, the presser 34 includes a first through-hole 34a and a second through-hole 34b. The first slide bar 32 is insertable into the first through-hole 34a, and the second slide bar 33 is insertable into the second through-hole 34b. The presser 34 may be moved upward, so that the second slide bar 33 is drawn out of the second through-hole 34b. In this state, the presser 34 is supported only by the first slide bar 32. As a result, as shown in FIG. 3, the presser 34 is rotatable in a direction of arrow A and a direction of arrow B about the first slide bar 32.

The presser 34 is moved to a first position P1 and a second position P2 by rotating in the direction of arrow A and the direction of arrow B. The presser 34 is located at the second position P2 in order to put the heat transfer foil 102 and the light absorbing film 103 into close contact with the transfer target 101. At the second position P2, the presser 34 is located above the holding table 20. At the second position P2, the presser is located between the holding table 20 and the light irradiation device 50. When the presser 34 is at the second position P2, the first slide bar 32 is inserted into the first through-hole 34a and the second slide bar 33 is inserted into the second through-hole 34b. The presser 34 is movable in a vertical direction in this state. When becoming free at the second position P2, the presser 34 falls downward and contacts the work 100 held by the holding table 20.

The presser 34 is located at the first position P1 in order to detach the holding table 20 from the base 31. When the presser 34 is at the first position P1, the first slide bar 32 is inserted into the first through-hole 34a, whereas the second slide bar 33 is not inserted into the second through-hole 34b. At the first position P1, the presser 34 is retracted from the position above the holding table 20.

As shown in FIG. 3 and FIG. 4, the presser 34 includes a light-transmissive portion 34c. The light-transmissive portion 34c is rectangular or substantially rectangular. The light-transmissive portion 34c is larger than the holding table 20. More specifically, the light-transmissive portion 34c is longer than the holding table 20 in the left-right direction and also in the front-rear direction. When the presser 34 is at the second position P2, the holding table 20 is located in the light-transmissive portion 34c as seen in a plan view. Therefore, the work 100 held by the holding table 20 is also located in the light-transmissive portion 34c as seen in a plan view.

In this preferred embodiment, the light-transmissive portion 34c is a glass plate fit into a rectangular or substantially rectangular through-hole formed in the presser 34. The glass plate transmits light from the light irradiation device 50. Thus, the light-transmissive portion 34c transmits light from the light irradiation device 50. The light which has transmitted the light-transmissive portion 34c reaches the work 100. The light-transmissive portion 34c, among the elements of the presser 34, contacts the work 100. The light-transmissive portion 34c presses the work 100 toward the holding table 20 (in this preferred embodiment, downward) to put the transfer target 101, the heat transfer foil 102 and the light absorbing film 103 into close contact with each other. The presser 34 presses the work 100 by a weight of its own. The pressing force of the presser 34 merely needs to be sufficient to put the transfer target 101, the heat transfer foil 102 and the light absorbing film 103 into close contact with each other, and does not need to be larger than that.

The stopper 35 restricts the rotation of the presser 34. As shown in FIG. 2, the stopper 35 extends upward from the base 31. The stopper 35 is located to the rear of the first slide bar 32. A top end of the stopper 35 is located above a top end of the second slide bar 33. As shown in FIG. 4, the stopper 35 restricts the presser 34 from rotating in the direction of arrow B beyond the second position P2. When the presser 34 is at the second position P2, the stopper 35 is in contact with the presser 34. The stopper 35 positions the presser 34 at the second position P2.

The head 40 is located above the holding table 20 and the pressing mechanism 30. The head 40 has the light irradiation device 50 mounted thereon. Therefore, the light irradiation device 50 is also located above, and away from, the holding table 20 and the pressing mechanism 30.

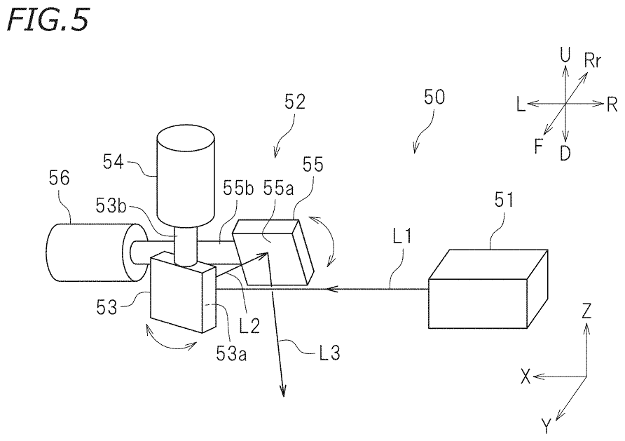

The light irradiation device 50 irradiates the work 100 held by the holding table 20 with light. The light absorbing film 103 of the work 100 generates heat upon receiving light from the light irradiation device 50. The heat generated by the light absorbing film 103 heats the heat transfer foil 102, and thus foil transfer is performed. FIG. 5 schematically shows a structure of the light irradiation device 50. As shown in FIG. 5, the light irradiation device 50 includes a light source 51 and an irradiation position moving mechanism 52. The irradiation position moving mechanism 52 includes a reflector including a reflective surface, and also includes a driver that changes the angle of the reflective surface. The irradiation position moving mechanism 52 moves a position irradiated with the light from the light source 51. The reflector is configured such that the angle of the reflective surface with respect to the light source 51 is changeable. The driver changes the angle of the reflective surface such that light reflected by the reflective surface moves in the Y-axis direction and the X-axis direction. In this preferred embodiment, as shown in FIG. 5, the irradiation position moving mechanism 52 includes a first mirror 53 and a second mirror 55 each defining and functioning as the reflector. The irradiation position moving mechanism 52 includes a first driver 54 and a second driver 56 each defining and functioning as the driver.

The light source 51 generates light for the foil transfer. In this preferred embodiment, the light source 51 generates laser light L1. The light source 51 is, for example, a laser diode. The light source 51 is connected with the controller 60, and is controlled by the controller 60.

As shown in FIG. 5, the laser light L1 generated by the light source 51 is directed toward the irradiation position moving mechanism 52. The laser light L1 is directed toward the first mirror 53 among the elements of the irradiation position moving mechanism 52. The first mirror 53 includes a reflective surface 53a reflecting light. The laser light L1 is directed toward the reflective surface 53a of the first mirror 53. The reflective surface 53a extends in a Z-axis direction. The first mirror 53 includes a rotation shaft 53b extending in the Z-axis direction, and is rotatable about the rotation shaft 53b. When the first mirror 53 is rotated, the orientation of the reflective surface 53a is changed along the horizontal plane. Therefore, the rotation of the first mirror 53 changes the direction of light L2, reflected by the first mirror 53, along the horizontal plane.

An end of the rotation shaft 53b of the first mirror 53 is connected with the first driver 54. The first driver 54 includes, for example, an electric motor. The first driver 54 changes the angle of the reflective surface 53a of the first mirror 53 such that the light L2 reflected by the reflective surface 53a advances in a desired direction. The first driver 54 is connected with the controller 60, and is controlled by the controller 60.

The light L2 reflected by the first mirror 53 is directed toward a reflective surface 55a of the second mirror 55. The second mirror 55 includes a rotation shaft 55b extending in the horizontal direction. The second mirror 55 is rotatable about the rotation shaft 55b. Thus, when the second mirror 55 is rotated about the rotation shaft 55b, the angle defined by the reflective surface 55a and the horizontal plane changes. Therefore, the rotation of the second mirror 55 changes the angle of reflected light L3, reflected by the second mirror 53, with respect to the horizontal plane.

An end of the rotation shaft 55a of the second mirror 55 is connected with the second driver 56. The second driver 56 also includes, for example, an electric motor. The second driver 56 changes the angle of the reflective surface 55a of the second mirror 55 such that the light L3 reflected by the reflective surface 55a advances in a desired direction. The second driver 56 is connected with the controller 60, and is controlled by the controller 60.

The rotation of the first mirror 53 by the first driver 54 and the rotation of the second mirror 55 by the second driver 56 change the direction in which the light L3 reflected by the second mirror 55 advances. The light irradiation device 52 irradiates the work 100 with the reflected light L3. The controller 60 controls the first driver 54 and the second driver 56 to move the position, on the work 100, that is irradiated with the light L3 from the light irradiation device 50. In this preferred embodiment, the work 100 is located to expand in the horizontal plane (X-Y plane). Therefore, the light L3 directed from the light irradiation device 50 toward the work 100 is moved on the work 100 two-dimensionally along the horizontal plane.

An operation of the foil transfer device 10 is controlled by the controller 60. The controller 60 is preferably a computer, for example. The controller 60 includes, for example, an interface (I/F) receiving foil transfer data or the like from an external device such as a host computer or the like, a central processing unit (CPU) executing a command of a control program, a ROM storing the program to be executed by the CPU, a RAM usable as a working area where the program is developed, and a storage device, such as a memory or the like, storing the above-described program and various types of data.

For a foil transfer process, the presser 34 is located at the second position P2. In this state, the light-transmissive portion 34c of the presser 34 presses the work 100, held by the holding table 20, downward. As a result, the transfer target 101, the heat transfer foil 102 and the light absorbing film 103 are put into close contact with each other. Since the light absorbing film 103 and the heat transfer foil 102 are in close contact with each other, the heat generated by the light absorbing film 103 is conducted to the heat transfer foil 102. Since the heat transfer foil 102 and the transfer target 101 are in close contact with each other, the decoration layer of the heat transfer foil 102 is transferred onto the surface of the transfer target 101.

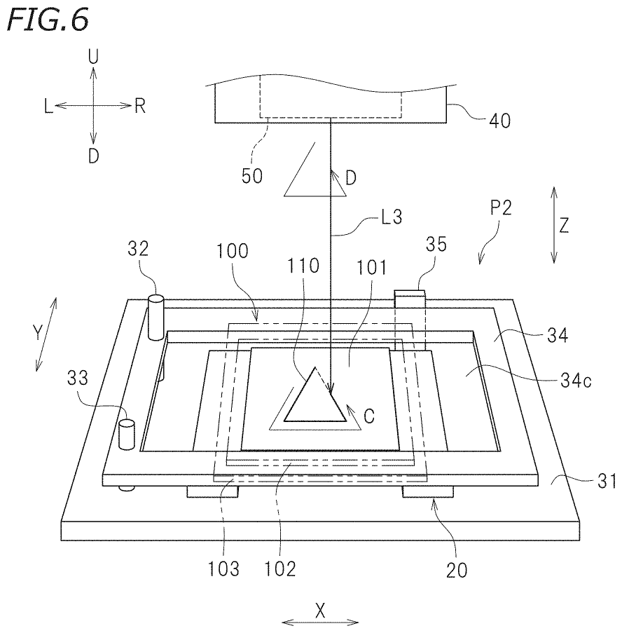

FIG. 6 is a perspective view schematically showing the work 100 during the foil transfer. As shown in FIG. 6, during the foil transfer, the presser 34 is located at the second position P2 and presses the work 100 downward. The work 100 is located in the light-transmissive portion 34c as seen in a plan view. The light-transmissive portion 34c is irradiated with the light L3 from the light irradiation device 50. The light L3 transmits the light-transmissive portion 34c and reaches the light absorbing film 103. In the case shown in FIG. 6, the light L3 moves in a direction of arrow C on the work 100. The light L3 is movable two-dimensionally on the work 100. The light L3 moves on the work 100 along an image 110 to be foil-transferred, so that the image 110 is transferred onto the transfer target 101. In FIG. 6, transfer of a portion, of the image 110, that is represented by the solid line has been finished. Transfer of a portion, of the image 110, that is represented by the dashed line has not been finished. In this state, the light L3 is moved in a direction of arrow D shown in FIG. 6.

In the foil transfer process, a portion, of the light absorbing film 103, that is irradiated with the laser light L3 from the light irradiation device 50 absorbs the laser light L3. This causes the optical energy to be converted into thermal energy. The heat generated by the light absorbing film 103 is conducted to the adhesive layer of the heat transfer foil 102. As a result, the adhesive layer is softened and expresses adhesiveness. The adhesive layer is attached to a surface of the decoration layer and a surface of the transfer target 101, and thus bonds the decoration layer and the transfer target 101 to each other. When, after this, the light L3 is moved and supply of the optical energy to the irradiated portion is finished, the adhesive layer is cooled by heat dissipation and is cured. This fixes the surface of the decoration layer and the surface of the transfer target 101 to each other, and thus the foil transfer of this portion is completed. Such an operation is continued while the position irradiated with the light L3 is changed, so that the foil transfer onto the transfer target 101 is completed.

As described above, the foil transfer device 10 according to this preferred embodiment includes the light irradiation device 50 spaced away from the holding table 20, and also includes the presser 34 between the holding table 20 and the light irradiation device 50. The light irradiation device 50 includes the irradiation position moving mechanism 52 moving the position, on the work 100, that is irradiated with the light from the light source 51. The presser 34 includes the light-transmissive portion 34c. The presser 34 presses the work 100 toward the holding table 20 to put the transfer target 101, the heat transfer foil 102 and the light absorbing film 103 into close contact with each other, and also transmits light from the light irradiation device 50 to allow the light to reach the work 100. In this preferred embodiment, the presser 34 puts the transfer target 101, the heat transfer foil 102 and the light absorbing film 103 into close contact with each other. The position irradiated with the light L3 is moved by the irradiation position moving mechanism 52 of the light irradiation device 50. The light L3 for the foil transfer transmits the light-transmissive portion 34c and reaches the work 100. In this manner, the foil transfer onto the transfer target 101 is performed with such a structure.

The foil transfer device 10 according to this preferred embodiment moves the transfer position more quickly than the conventional foil transfer device. This improves the productivity of foil-transferred images. The conventional foil transfer device heats the heat transfer foil while the foil transfer tool presses the heat transfer foil from above. As the foil transfer tool, for example, an optical pen that directs laser light is used. However, the foil transfer tool is moved while pressing the heat transfer foil and the transfer target during the foil transfer. Due to the load of pressing the work, it is difficult to move the foil transfer tool on the work at a high speed. For this reason, the conventional foil transfer device cannot move the transfer position on the transfer target at a high speed, and thus does not provide a high productivity.

By contrast, in the foil transfer device 10 according to this preferred embodiment, unlike in the conventional foil transfer device, the position irradiated with the light L3 is moved by the irradiation position moving mechanism 52 regardless of the operation of pressing the work 100. The movement of the position irradiated with the light L3 by the irradiation position moving mechanism 52 is not influenced by the operation of pressing the work 100. Therefore, the foil transfer device 10 according to this preferred embodiment moves the transfer position quickly and thus improves the productivity of foil-transferred images.

The foil transfer device 10 according to this preferred embodiment includes the irradiation position moving mechanism 52 configured to move, in the X-axis direction and the Y-axis direction, the position irradiated with the light. Such a structure does not need a moving device that moves the light irradiation device 50 or the holding table 20 in the X-axis direction and the Y-axis direction, and thus simplifies the structure of the foil transfer device 10. In this preferred embodiment, the irradiation position moving mechanism 52 includes the first mirror 53 and the second mirror 55 respectively configured such that the angles of the reflective surfaces 53a and 55a with respect to the light source 51 are changeable, and also includes the first driver 54 and the second driver 56 respectively changing the angles of the reflective surfaces 53a and 55a. Such a structure allows the position irradiated with the light L3 from the light irradiation device 50 to be moved freely.

According to this preferred embodiment, the presser 34 is provided above the holding table 20 and presses the work 100 using its own weight. Such a structure does not need, for example, a mechanism that presses the presser toward the holding table 20 by an actuator, and thus simplifies the structure of the foil transfer device 10.

In this preferred embodiment, the light-transmissive portion 34a of the presser 34 is formed of glass. Glass transmits light favorably, and also may be formed to be flat and is not easily warped by being pressed. Glass also has a high resistance against heat. Therefore, glass is preferably usable for the light-transmissive portion 34a.

### Preferred Embodiment 2

A foil transfer device according to preferred embodiment 2 includes a mechanism that moves a light irradiation device in a first direction (e.g., X-axis direction) and the light irradiation device that moves the position irradiated with light in a second direction (e.g., Y-axis direction) perpendicular to the first direction. Preferred embodiment 2 is the same as preferred embodiment 1 except for this. Thus, in preferred embodiment 2, elements common to those in preferred embodiment 1 will bear the identical reference signs thereto, and overlapping descriptions will be omitted or simplified.

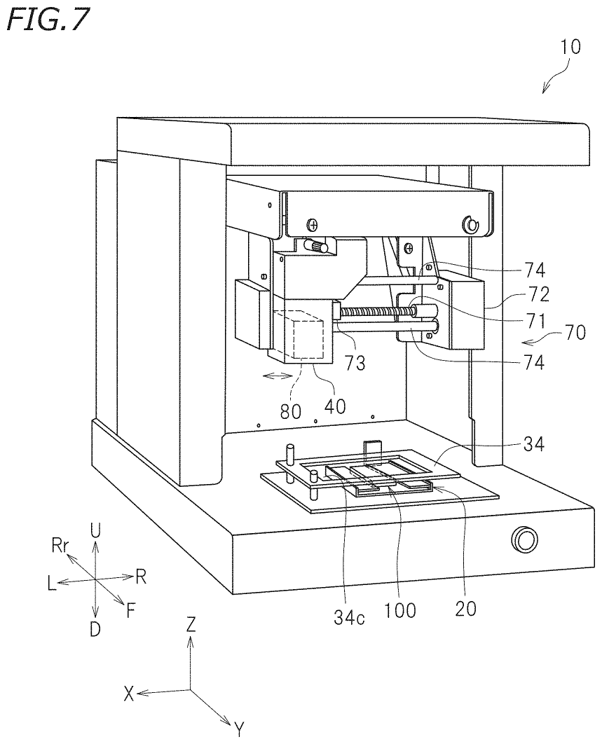

FIG. 7 is a perspective view of a foil transfer device 10 according to preferred embodiment 2. As shown in FIG. 7, the foil transfer device 10 according to this preferred embodiment includes an X-axis direction moving device 70 moving the head 40 in the X-axis direction and a light irradiation device 80 configured to move, in the Y-axis direction, the light directed toward the work 100.

The X-axis direction moving device 70 is configured to move the light irradiation device 80 in the X-axis direction with respect to the holding table 20. In this preferred embodiment, the X-axis direction moving device 70 moves the light irradiation device 80 via the head 40. As shown in FIG. 7, the X-axis direction moving device 70 includes a feeding screw rod 71, a driving motor 72, a feeding nut 73 and a pair of slide shafts 74. The feeding screw rod 71 extends in the X-axis direction. The feeding screw rod 71 includes a spiral thread. One end of the feeding screw rod 71 is coupled with the driving motor 72. The driving motor 72 is connected with the controller 60, and is controlled by the controller 60. The driving motor 72 is controlled by the controller 60 to rotate the feeding screw rod 71. The feeding screw rod 71 is engaged with the feeding nut 73. The feeding nut 73 is attached to the head 40. The pair of slide shafts 74 are located parallel or substantially parallel to the feeding screw rod 71. The head 40 is engaged with the slide shafts 74 so as to be slidable in the X-axis direction. When the driving motor 72 is driven, the head 40 moves in the X-axis direction along the slide shafts 74 by the rotation of the feeding screw rod 71.

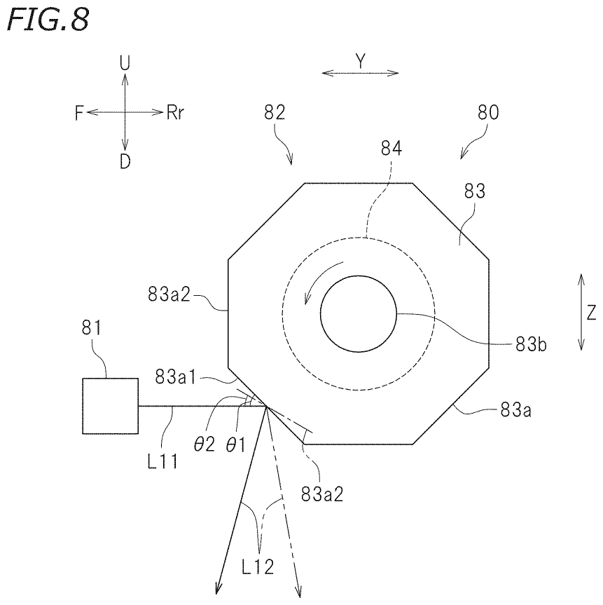

FIG. 8 is a side view schematically showing a structure of the light irradiation device 80. As shown in FIG. 8, the light irradiation device 80 according to this preferred embodiment includes a light source 81 and an irradiation position moving mechanism 82. The irradiation position moving mechanism 82 includes a polygon mirror 83 and a driver 84.

As shown in FIG. 8, the light source 81 generates laser light L11. The light source 81 is connected with the controller 60, and is controlled by the controller 60. The laser light L11 generated by the light source 81 is directed toward the polygon mirror 83.

The polygon mirror 83 is polygonal column-shaped. As shown in FIG. 8, the polygon mirror 83 is located so as to appear polygonal as seen in the X-axis direction (as seen in the left-right direction). A plurality of side surfaces of the polygonal column are each a reflective surface 83a. The plurality of reflective surfaces 83a reflect the light directed thereto. The light source 81 directs the laser light L11 toward one of the reflective surfaces 83a of the polygon mirror 83 from a position to the front of the polygon mirror 83.

The polygon mirror 83 includes a rotation shaft 83b extending in the X-axis direction. The polygon mirror 83 is rotatable about the rotation shaft 83b. The polygon mirror 83 is rotated by the driver 84. The driver 84 includes, for example, an electric motor. The driver 84 is connected with the controller 60, and is controlled by the controller 60. The driver 84, when being driven, rotates the polygon mirror 83 at a constant speed.

The light source 81 is controlled to be turned on/off in accordance with the rotation of the polygon mirror 83. The light source 81 irradiates, for example, a first reflective surface 83a1 of the polygon mirror 83 with the laser light L11 at a timing when an angle defined by the first reflective surface 83a1 and the horizontal plane is first angle θ1. As a result, light L12 reflected by the first reflective surface 83a1 is directed toward a first position on the work 100 placed below the light irradiation device 80. The light source 81 further irradiates a second reflective surface 83a2, which is a reflective surface next to the first reflective surface 83a1 in the rotation direction of the polygon mirror 83, with the laser light L11. At this point, the second reflective surface 83a2 and the horizontal plane make angle θ2. The light L11 directed toward the second reflective surface 83a2 is reflected as the reflected light L12, which is directed toward a second position on the work 100. The second position is away from the first position in the Y-axis direction. After this, substantially the same operation is repeated to move the position irradiated with the reflected light L12 in the Y-axis direction.

In a foil transfer process, in this preferred embodiment also, the work 100 is pressed by the presser 34. The position, on the work 100, that is irradiated with the light L12 from the light irradiation device 80 is moved two-dimensionally as a result of the light L12 being moved in the Y-axis direction by the irradiation position moving mechanism 82 and the light irradiation device 80 being moved in the X-axis direction by the X-axis direction moving device 70. In this manner, the light L12 is directed toward a desired position on the work 100. Therefore, a desired image is foil-transferred onto the transfer target 101.

As can be seen, in this preferred embodiment, the irradiation position moving mechanism 82 is configured to move the position irradiated with the light L12 in the Y-axis direction. The foil transfer device 10 includes the X-axis moving device 70 moving the light irradiation device 80 in the X-axis direction with respect to the holding table 20. Such a structure also moves the transfer position quickly in foil transfer for substantially the same reason as in preferred embodiment 1, and thus improves the productivity of foil-transferred images.

In this preferred embodiment, the irradiation position moving mechanism 82 includes the polygon mirror 83 configured such that the angle of the reflective surface 83a with respect to the light source 81 is changeable, and also includes the driver 84 changing the angle of the reflective surface 83a such that the light L12 reflected by the reflective surface 83a is moved in the Y-axis direction. Such a structure also moves the position irradiated with the light L12, directed from the light irradiation device 80, freely in the Y-axis direction.

In this preferred embodiment, the light irradiation device 80 is movable whereas the holding table 20 is immovable. The present invention is not limited to such a structure. The movement of the light irradiation device 80 and the holding table 20 is relative. There is no specific limitation on which of the light irradiation device 80 and the holding table 20 is movable.

### Preferred Embodiment 3

A foil transfer device according to preferred embodiment 3 includes a moving mechanism that moves a light irradiation device two-dimensionally with respect to the holding table, but does not include an irradiation position moving mechanism that moves the position irradiated with the light. In preferred embodiment 3 also, elements common to those in preferred embodiment 1 or preferred embodiment 2 will bear the identical reference signs thereto, and overlapping descriptions will be omitted or simplified.

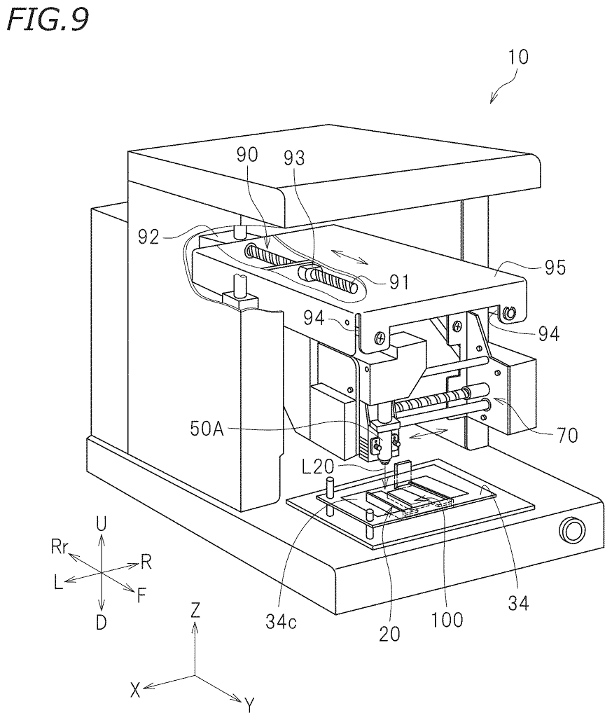

FIG. 9 is a partially-cut perspective view of a foil transfer device 10 according to preferred embodiment 3. As shown in FIG. 9, the foil transfer device 10 further includes a Y-axis direction moving device 90 moving a light irradiation device 50A in the Y-axis direction. In this preferred embodiment, the light irradiation device 50A does not include an irradiation position moving mechanism that moves the position irradiated with the light. In this preferred embodiment, the light irradiation device 50A directs light L20 downward.

As shown in FIG. 9, the Y-axis direction moving device 90 includes a feeding screw rod 91, a driving motor 92, a feeding nut 93 and a pair of slide shafts 94. The feeding screw rod 91 extends in the Y-axis direction. The driving motor 92 is connected with the controller 60, and is controlled by the controller 60. The driving motor 92 is controlled by the controller 60 to rotate the feeding screw rod 91. A thread of the feeding screw rod 91 is engaged with the feeding nut 93. The feeding nut 93 is attached to a slide base 95. The pair of slide shafts 94 are located parallel to the feeding screw rod 91. The slide base 95 is engaged with the slide shafts 94 so as to be slidable in the Y-axis direction. When the driving motor 92 is driven, the slide base 95 moves in the Y-axis direction along the slide shafts 94 by the rotation of the feeding screw rod 91. The X-axis direction moving device 70 is attached to the slide base 95. Thus, the light irradiation device 50A is moved in the Y-axis direction and the X-axis direction respectively by the Y-axis direction moving device 90 and the X-axis direction moving device 70.

In this preferred embodiment, the position on the work 100 that is irradiated with the light L20 from the light irradiation device 50A during foil transfer is moved two-dimensionally as a result of the light irradiation device 50A being moved in the Y-axis direction by the Y-axis direction moving device 90 and the light irradiation device 50A being moved in the X-axis direction by the X-axis direction moving device 70. In this manner, the transfer position is moved.

As can be seen, the foil transfer device 10 according to this preferred embodiment includes the Y-axis direction moving device 90 moving the light irradiation device 50A in the Y-axis direction with respect to the holding table 20, and also includes the X-axis direction moving device 70 moving the light irradiation device 50A in the X-axis direction with respect to the holding table 20. Such a structure also moves the transfer position during the foil transfer quickly for substantially the same reason as in preferred embodiments 1 and 2, and thus improves the productivity of foil-transferred images.

The foil transfer device 10 may further include a Z-axis direction moving device that moves the light irradiation device 50A or the holding table 20 in the Z-axis direction. The Z-axis direction moving device is used to, for example, keep constant the distance between the work 100 and the light irradiation device 50A regardless of the level of the work 100. The Z-axis direction moving device may be included in the foil transfer device in the preferred embodiment 1 or preferred embodiment 2.

Some preferred embodiments of the present invention are described above. The above-described preferred embodiments are merely examples, and the present invention may be carried out in any of various other forms. For example, in the above-described preferred embodiments, the irradiation position moving mechanism includes the mirror as a reflector and a driver that changes the angle of the mirror. The irradiation position moving mechanism does not need to have such a structure. The irradiation position moving mechanism may be configured to, for example, change the orientation of the light source.

In the above-described preferred embodiments, the presser presses the transfer target, the heat transfer foil and the light absorbing film by the weight of its own. Alternatively, the presser may press the work by, for example, a force generated by an actuator. Still alternatively, the presser may press the work by, for example, an elastic force of an elastic member such as a spring or the like. The presser does not need to be a flat plate, and may have a shape in accordance with the three-dimensional shape of the work.

In the above-described preferred embodiments, the presser is configured to be positioned with respect to the work by the slide bars. The foil transfer device does not need to include such a positioning mechanism. The presser may be detachable from a main body of the foil transfer device. For example, the presser may be formed only of a glass plate having an appropriate weight, or may be merely placed on the work.

In preferred embodiment 2 or preferred embodiment 3 described above, the light irradiation device is moved in one direction or two directions perpendicular to the direction in which the transfer target, the heat transfer foil and the heat generator overlap each other. The direction in which the light irradiation device or the holding table is moved does not need to be perpendicular to, and merely needs to be non-parallel to, the direction in which the transfer target, the heat transfer foil and the heat generator overlap each other. The foil transfer device may include, for example, a moving device that moves the light irradiation device on any plane, a holding table that holds the work such that the work is inclined with respect to the plane on which the light irradiation device is moved, and a presser that presses the work toward the holding table. The direction in which the light irradiation device directs light does not need to match the direction in which the transfer target, the heat transfer foil and the heat generator overlap each other, and may be appropriately set.

The terms and expressions used herein are for description only and are not to be interpreted in a limited sense. These terms and expressions should be recognized as not excluding any equivalents to the elements shown and described herein and as allowing any modification encompassed in the scope of the claims. The present invention may be embodied in many various forms. This disclosure should be regarded as providing preferred embodiments of the principles of the present invention. These preferred embodiments are provided with the understanding that they are not intended to limit the present invention to the preferred embodiments described in the specification and/or shown in the drawings. The present invention encompasses any of preferred embodiments including equivalent elements, modifications, deletions, combinations, improvements and/or alterations which can be recognized by a person of ordinary skill in the art based on the disclosure. The elements of each claim should be interpreted broadly based on the terms used in the claim, and should not be limited to any of the preferred embodiments described in this specification or referred to during the prosecution of the present application.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A foil transfer device, comprising:
a holding table to hold a work;
a light irradiation device spaced away from the holding table to irradiate the work held by the holding table with light; and
a presser between the holding table and the light irradiation device; wherein
the work includes a transfer target, a heat transfer foil and a heat generator that are stacked on each other, the heat generator generating heat upon receiving the light from the light irradiation device;
the holding table holds the work such that the transfer target, the heat transfer foil and the heat generator face the presser;
the light irradiation device includes:
a light source; and
an irradiation position moving mechanism to move a position irradiated with light from the light source; and
the presser includes a light-transmissive portion to press the work toward the holding table to put the transfer target, the heat transfer foil and the heat generator into contact with each other, and to transmit the light from the light irradiation device to allow the light to reach the work.

2. The foil transfer device according to claim 1, wherein
the holding table holds the work such that the work expands in a first direction and a second direction perpendicular or substantially perpendicular to the first direction; and
the irradiation position moving mechanism is configured to move a position on the work that is irradiated with the light in the first direction and the second direction.

3. The foil transfer device according to claim 2, wherein the irradiation position moving mechanism includes:
a reflector that includes a reflective surface to reflect the light from the light source and configured such that an angle of the reflective surface with respect to the light source is changeable; and
a driver to change the angle of the reflective surface such that the light reflected by the reflective surface moves in the first direction and the second direction.

4. The foil transfer device according to claim 1, wherein
the holding table holds the work such that the work expands in a first direction and a second direction perpendicular or substantially perpendicular to the first direction;
the irradiation position moving mechanism is configured to move a position on the work that is irradiated with the light in the first direction; and
the foil transfer device includes a moving device that moves the light irradiation device in the second direction with respect to the holding table.

5. The foil transfer device according to claim 4, wherein the irradiation position moving mechanism includes:
a reflector that includes a reflective surface to reflect the light from the light source and configured such that an angle of the reflective surface with respect to the light source is changeable; and
a driver that changes the angle of the reflective surface such that the light reflected by the reflective surface moves in the first direction.

6. The foil transfer device according to claim 1, wherein the presser is provided above the holding table to press the work by its own weight.

7. The foil transfer device according to claim 1, wherein the light-transmissive portion is made of glass.

8. A foil transfer device, comprising:
a holding table to hold a work;
a light irradiation device spaced away from the holding table to irradiate the work held by the holding table with light;
a moving device that moves the light irradiation device with respect to the holding table; and
a presser between the holding table and the light irradiation device; wherein
the work includes a transfer target, a heat transfer foil and a heat generator stacked on each other, the heat generator generating heat upon receiving the light from the light irradiation device;
the holding table holds the work such that the transfer target, the heat transfer foil and the heat generator face the presser;
the moving device includes:
a first moving device to move the light irradiation device in a first direction with respect to the holding table, the first direction being non-parallel to a direction in which the transfer target, the heat transfer foil and the heat generator being stacked on each other; and
a second moving device to move the light irradiation device in a second direction with respect to the holding table, the second direction being non-parallel to the direction in which the transfer target, the heat transfer foil and the heat generator being stacked on each other and also non-parallel to the first direction; and
the presser includes a light-transmissive portion to press the work toward the holding table to put the transfer target, the heat transfer foil and the heat generator into contact with each other, and to transmit the light from the light irradiation device to allow the light to reach the work.

9. The foil transfer device according to claim 8, wherein the presser is provided above the holding table to press the work by its own weight.

10. The foil transfer device according to claim 8, wherein the light-transmissive portion is made of glass.
